(19) United States
(12) Patent Application Publication
(10) Pub. No.: US 2023/0215815 A1
(43) Pub. Date: Jul. 6, 2023

(54) WAFER AND METHOD OF MAKING, AND SEMICONDUCTOR DEVICE

(71) Applicant: ChangXin Memory Technologies, Inc., Hefei City (CN)

(72) Inventor: Ping-Heng WU, Hefei City (CN)

(21) Appl. No.: 17/040,506

(22) PCT Filed: Jan. 16, 2020
(86) PCT No.: PCT/CN2020/072496

§ 371 Date: Mar. 27, 2023

(30) Foreign Application Priority Data
Jun. 28, 2019 (CN) 201910579219.4

(51) Int. Cl. H01L 23/00; H01L 23/544

(52) U.S. Cl. CPC H01L 23/562; H01L 23/544; H01L 2223/5446

(57) ABSTRACT

The present disclosure relates to a wafer, a manufacturing method thereof, and a semiconductor device. The wafer manufacturing method includes: providing a wafer having a scribe lane for die cutting. A plurality of through-silicon-vias for cracking stress release and prevention is formed on one side of the scribe lane, and the through-silicon-vias are filled with a protective material. Through the technique of through-silicon vias filled with protective materials on both sides of the scribe lane, the cutting stress can prevent damage to the die area during wafer cutting. The through-silicon-vias can effectively reduce the scribe lane width, which is conducive to miniaturizing the scribe lane and improving the effective utilization of wafers.

### CROSS REFERENCES TO RELATED APPLICATIONS

This application is a national phase entry of International Application No. PCT/CN2020/072496 filed on Jan. 16, 2020, which claims the benefit of priority to CN Patent Application CN201910579219.4 filed on Jun. 28, 2019, both entitled “WAFER AND METHOD OF MAKING, AND SEMICONDCUTOR DEVICE”, the contents of which are incorporated herein by reference in its entirety.

### TECHNICAL FIELD

The present disclosure relates to the field of semiconductor technology, and in particular to a wafer, a manufacturing method thereof, and a semiconductor device.

### BACKGROUND

With the development of integrated circuit (IC) technology, the integration level of IC chips is getting ever higher, single-wafer chips can no longer meet the requirements, therefore stacked chips built on multiple wafers have become more widely used. Stacked chips are built by cutting through multi-stacked wafers.

A multi-stacked wafer includes die areas and a cutting areas. The die areas may be damaged due to the stress of the cutting operation in the cutting areas. In order to ensure that the die areas are not damaged during cutting, relatively large cutting areas are applied currently. However, the large cutting area results in a reduction in the effective utilization of the wafer and thus an increase in chip cost.

It should be noted that the information disclosed in the above background section is only used to enhance the understanding of the background of the present disclosure, therefore may include information that does not constitute the information known to those of ordinary skill in the art.

### SUMMARY

The present disclosure provides a wafer, a manufacturing method thereof, and a semiconductor device, thereby overcoming the problems caused by the limitations and defects of related technologies.

According to a first aspect of the present disclosure, a wafer manufacturing method is provided, which includes: providing a first wafer having a first scribe lane for die cutting; forming a plurality of first crack-stopping through-silicon-via (TSV) holes on a side of the first scribe lane, wherein each of the plurality of first crack-stopping through-silicon-via holes is filled with a protective material.

In some examples, the plurality of first crack-stopping through-silicon-via holes are formed on a first surface of the first wafer, wherein the plurality of first crack-stopping through-silicon-via holes does not penetrate a full thickness of the first wafer; wherein the first wafer has a second surface opposite to the first surface; and wherein the wafer manufacturing method further comprises thinning the second surface of the first wafer until the plurality of first crack-stopping through-silicon-via holes is exposed.

In another example, the method further includes: providing a second wafer having a second scribe lane for die cutting; forming a plurality of second crack-stopping through-silicon-via holes on a side of the second scribe lane, wherein the second wafer is stacked with the first wafer; wherein the plurality of second crack-stopping through-silicon-via holes each is aligned to one of the plurality of first crack-stopping through-silicon-via holes; and wherein each of the plurality of second crack-stopping through-silicon-via holes is filled with the protective material.

In some examples, the plurality of first crack-stopping through-silicon-via holes is formed on both sides and along an extending direction of the first scribe lane.

In some examples, the plurality of first crack-stopping through-silicon-via holes comprises continuously distributed or separately distributed crack-stopping through-silicon-via holes.

In some examples, the plurality of first crack-stopping through-silicon-via holes is distributed in multiple rows on one side of the scribe lane.

In some examples, the width of each of the plurality of first crack-stopping through-silicon-via holes is in the range from 2 microns to 20 microns, and the depth of each of the plurality of first crack-stopping through-silicon-via holes is in the range from 15 microns to 150 microns.

In some examples, the protective material comprises one or more of copper, tungsten, aluminum, tantalum, titanium, tantalum nitride, titanium nitride, silicon oxide, silicon nitride, silicon oxynitride, carbide silicon, silicon carbonitride, polyimide and tetraethyl orthosilicate.

In some examples, air gaps are provided in at least one of the plurality of first crack-stopping through-silicon-via holes.

According to a second aspect of the present disclosure, a wafer is disclosed which includes: a wafer substrate, having a scribe lane for die cutting; a plurality of crack-stopping through-silicon-via holes on a side of the scribe lane, wherein each of the plurality of crack-stopping through-silicon-via holes is filled with a protective material.

In some examples, the plurality of crack-stopping through-silicon-via holes is formed on both sides and along an extending direction of the scribe lane.

In some examples, the plurality of crack-stopping through-silicon-via holes comprises continuously distributed or separately distributed crack-stopping through-silicon-via holes.

In some examples, the plurality of crack-stopping through-silicon-via holes is distributed in multiple rows on one side of the scribe lane.

In some examples, wherein the width of each of the plurality of crack-stopping through-silicon-via holes is in the range from 2 microns to 20 microns, and the depth of each of the plurality of holes is in the range from 15 microns to 150 microns.

In some examples, the protective material comprises one or more of copper, tungsten, aluminum, tantalum, titanium, tantalum nitride, titanium nitride, silicon oxide, silicon nitride, silicon oxynitride, carbide silicon, silicon carbonitride, polyimide and tetraethyl orthosilicate.

In some examples, air gaps are provided in at least one of the plurality of crack-stopping through-silicon-via holes.

In the third aspect of the disclosure, a semiconductor device is described which includes multiple wafers each being disclosed above, and these multiple wafers are stacked together.

It should be understood that the above general description and the following detailed description are only exemplary and explanatory, and cannot limit the present disclosure.

### BRIEF DESCRIPTION OF THE DRAWINGS

The drawings are incorporated into the specification and constitute a part of the specification, in accordance with the embodiments of the current disclosure. Together with the specification to explain the principle of the disclosure. The drawings in the following description show only some embodiments of the present disclosure. For those of ordinary skill in the art, other drawings can be obtained based on these drawings without creative work.

FIG. 1 is a flowchart of a first wafer manufacturing method according to an exemplary embodiment of the present disclosure.

FIG. 2 is a flowchart of a second wafer manufacturing method according to an exemplary embodiment of the present disclosure.

FIG. 3 is a flowchart of a third wafer fabrication method according to an exemplary embodiment of the present disclosure.

FIG. 4 is a schematic top view of a wafer according to an exemplary embodiment of the present disclosure.

FIG. 5 is a schematic cross-sectional view of a wafer according to an exemplary embodiment of the present disclosure.

FIGS. 6 to 9 show process diagrams during the forming of crack-stopping through-silicon-vias according to an exemplary embodiment of the present disclosure.

FIGS. 10 and 11 show process diagrams during the forming of another type of crack-stopping through-silicon-vias according to some exemplary embodiments of the present disclosure.

FIG. 12 is a schematic diagram of the distribution of crack-stopping through-silicon-vias according to an exemplary embodiment of the present disclosure.

FIG. 13 is a schematic diagram of a crack-stopping through-silicon-via according to an exemplary embodiment of the present disclosure.

FIG. 14 is a schematic diagram of the distribution of another type of crack-stopping through-silicon-vias according to an exemplary embodiment of the present disclosure.

The following list shows the reference numerals in the figures:
100, wafer body; 110, die; 120, scribe lane; 200, crack-stopping through-silicon-via; 210, blind via; 230, first crack-stopping through-silicon-vias; 240, second crack-stopping through-silicon-vias; 250, air gap; 20, protective material layer; 300, the first wafer; 400, the second wafer.

### DETAILED DESCRIPTION

Exemplary embodiments will now be described more fully with reference to the accompanying drawings. However, the exemplary embodiments can be implemented in various forms, and should not be construed as being limited to the embodiments set forth herein; on the contrary, these embodiments are provided so that the present invention will be comprehensive and complete, and fully convey the concept of the exemplary embodiments to those skilled in the art. The same reference numeral in the figures represents the same or similar structures, and thus their detailed descriptions will be omitted.

Although relative terms such as “upper” and “lower” are used in this specification to describe the relative relationship of one component of an icon to another, these terms are used in this specification only for convenience, for example, the direction of an exemplary part as described in the drawings. It can be understood that if a component of the device is turned upside down, the component described as “upper” will become the “lower” component. When a structure is “on” another structure, it may mean that a certain structure is integrally formed on another structure, or that a certain structure is “directly” arranged on another structure, or that a certain structure is “indirectly” arranged on another structure through the third structure.

The terms “one”, “a”, “the”, “said” and “at least one” are used to indicate the presence of one or more elements/components/etc.; the terms “including” and “comprising” are used to indicate open-ended inclusive, may mean that in addition to the listed elements/components/etc., there may be other elements/components/etc.; the terms “first”, “second” and “third” are only used as a label, not a limit to the number of objects.

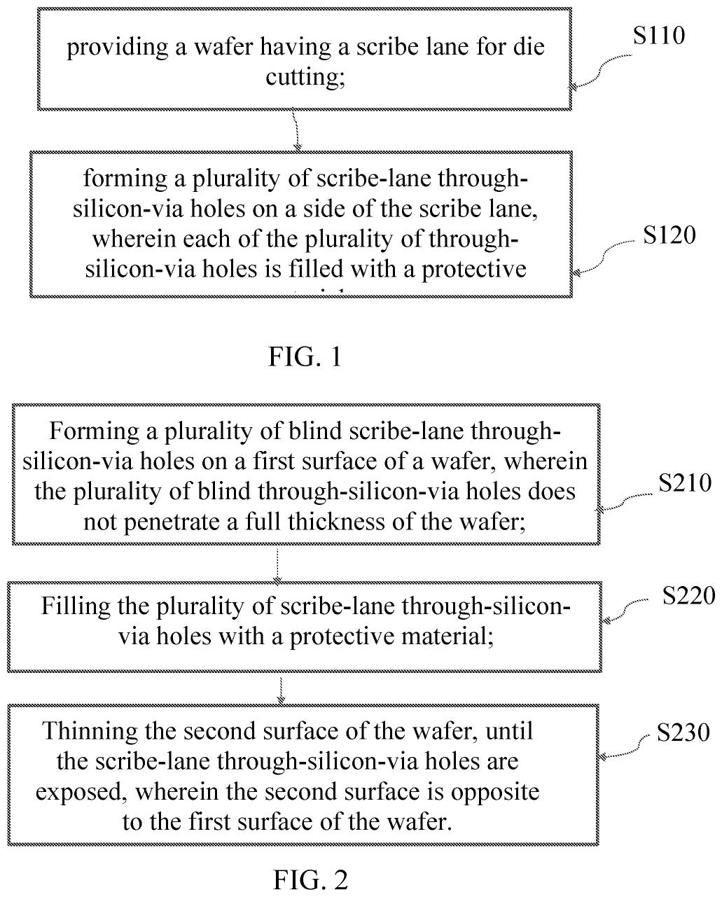

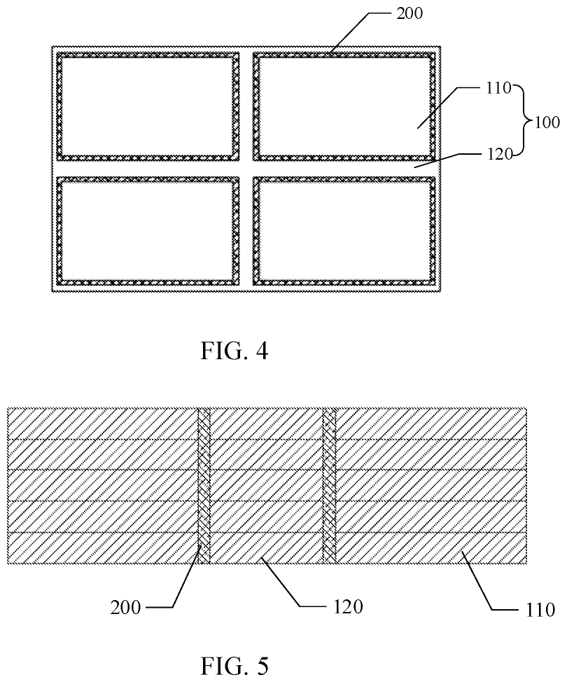

This exemplary embodiment provides a first wafer manufacturing method. As shown in FIG. 1 combined with FIG. 4, the wafer manufacturing method may include the following steps:

Step S110, providing a wafer body 100 with a scribe lane 120 for cutting;

Step S120, a crack-stopping through-silicon-via 200 is formed on the side of the scribe lane 120, and the through-silicon-via is filled with a protective material.

In the wafer fabrication method provided by the embodiments of the present disclosure, providing crack-stopping through-silicon-vias 200 on both sides of the scribe lane 120 and filling them with protective materials, cutting stress is prevented from damaging the die region 110 during wafer cutting. The crack-stopping through-silicon-via 200 can effectively reduce the width of the scribe lane 120 and miniaturize the scribe lane 120, thus improving the effective wafer utilization.

In step S110, the wafer body 100 may be divided into a scribe lane 120 and a die area 110. The cutting knife acts on the scribe lane 120 during cutting, and the die area 110 is untouched. The wafer body 100 may include silicon based substrate such as a silicon epitaxial wafer, silicon-on-insulator, etc., or a substrate of other semiconductor materials such as GaN, and the substrate may be an intrinsic semiconductor substrate, or N-type doped or P-type doped semiconductor substrate, but is not limited by the present disclosure. A dielectric layer may be provided on the substrate, and the material of the dielectric layer may be one or more of silicon oxide, silicon nitride, or silicon oxynitride. The dielectric layer may be formed by methods such as chemical vapor deposition, atomic layer deposition, and the like, in specific implementations. It is understood that the dielectric layer may be formed of one layer of insulating material, or may be formed by stacking multiple layers of the same or different insulating materials.

In a feasible implementation manner provided by the embodiment of the present disclosure, step S120 may include the following steps as shown in FIG. 2:

In step S210, a blind hole (not-through-the-silicon) 210 is formed on one side of the scribe lane 120 on the first surface of the wafer body 100;
In step S220, the blind hole 210 is filled with a protective material;
In step S230, the second surface of the wafer body 100 is thinned until the blind hole 210 is exposed, and the second surface is opposite to the first surface.
In step S210, as shown in FIG. 6, a blind hole 210 is formed on the side of the scribe lane 120 on the first surface of the wafer body 100. Herein the blind hole 210 may be formed by dry etching, wet etching, laser etching, or dry and wet etching combined. For example, dry etching may be reactive ion etching or inductively coupled plasma etching, and wet etching may be etching with hydrofluoric acid solution, hydrofluoric acid buffered etching solution, potassium hydroxide solution, or TMAH solution. The blind hole 210 is located at the side of the scribe lane 120, and the cross section of the blind hole 210 may be rectangular or trapezoidal.

It should be noted that the position of the blind hole 210 can be defined by photoresist, the photoresist can be coated on the first side of the wafer body 100, and the corresponding photomask can be exposed to transfer the pattern of the photomask to the photoresist. By developing, the photoresist layer exposes to where the crack-stopping silicon via 200 is to be opened; the blind hole 210 is formed by etching the silicon wafer but stopping before etching through the wafer.

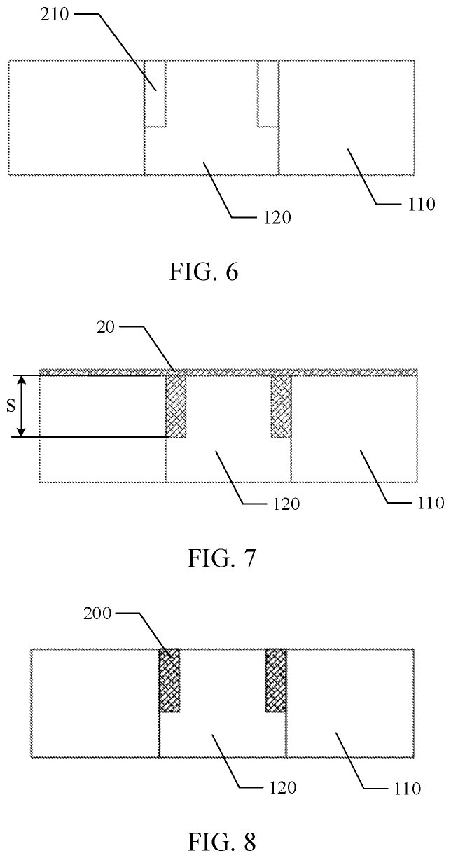

In step S220, as shown in FIG. 7, a protective material may be filled in the blind hole 210. The protective material can be one or more of conductive materials such as copper, tungsten, aluminum, tantalum, titanium, tantalum nitride, and titanium nitride. Before the protective material, an insulating layer can be deposited on the top surface of the wafer body 100 and on the inside walls of the blind hole 210. For example, the insulating layer can be formed by chemical vapor deposition, physical vapor deposition, or thermal growth. The above-mentioned conductive material then fills in the blind hole 210, by electroplating, for example. In electroplating, a seed layer is first deposited on the insulating layer, and a metal protective layer is electroplated on the seed layer. During the electroplating process, a metal layer is also formed on the first surface of the wafer body 100 outside the blind hole 210, so the metal layer needs to be removed from the wafer top surface, by etching or chemical mechanical polishing, for example.

When the filling material is one or more of silicon oxide, silicon nitride, silicon oxynitride, silicon carbide, silicon carbonitride, polyimide, and tetraethyl orthosilicate, techniques like chemical vapor deposition or physical vapor deposition or thermal growth may be applied. At the same time, as shown in FIG. 7, a protective material layer 20 is formed on the top surface of the wafer body 100. The protective material layer 20 can be removed or not removed according to actual needs. Further, as shown in FIG. 13, air gap holes 250 may be formed inside the protective material filling the blind hole 210.

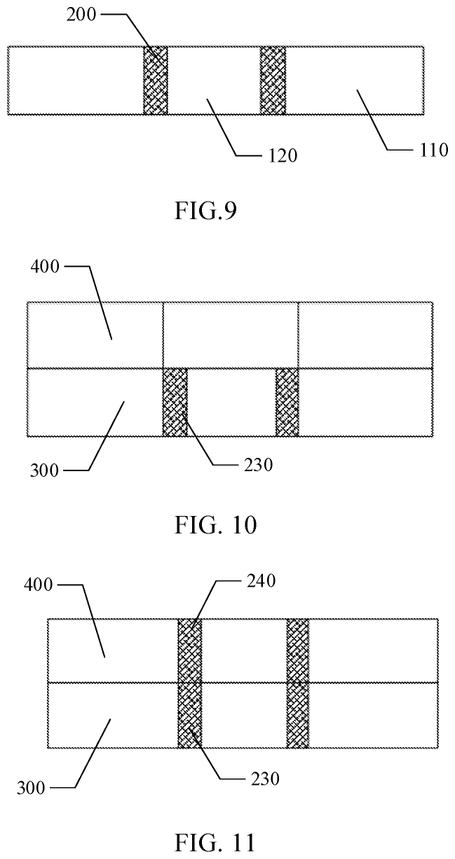

In step S230, as shown in FIG. 9, the second surface of the wafer body 100 is thinned until the blind hole 210 is exposed. The second surface of the wafer body 100 may be thinned by etching or chemical mechanical polishing. The second surface of the wafer body 100 is opposite to the first surface. For example, the first surface of the wafer body 100 may be the front side of the wafer body 100 is the second side is the back side of the wafer body 100.

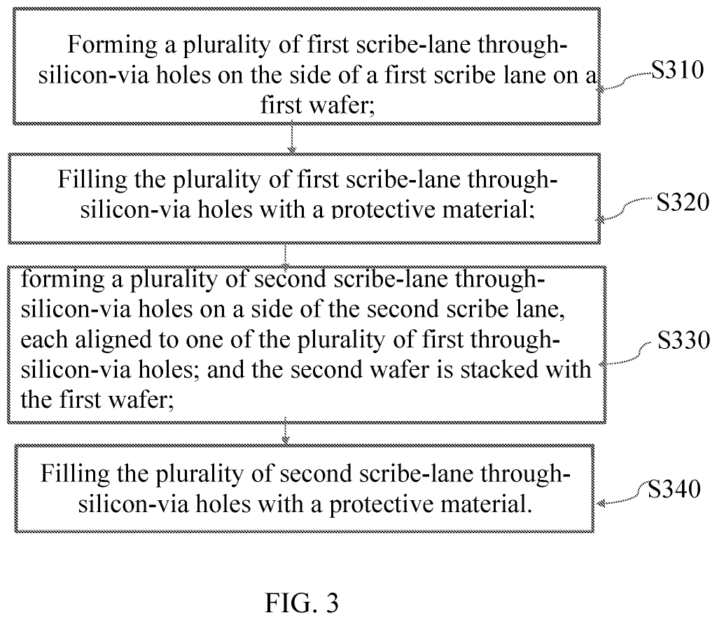

In a feasible implementation method provided by the embodiment of the present disclosure, as shown in FIG. 3, step S120 may include:

In step S310, forming a first crack-stopping through-silicon-via 230 on the side of the scribe line 120 on the first wafer body 300;

In step S320, filling the first crack-stopping through-silicon-via 230 with a protective material;

In step S330, a second crack-stopping through-silicon-via 240 is formed on the side of the scribe lane on the second wafer body 400, and is formed to align to the first crack-stopping through-silicon-via 230. The first wafer body 300 and the second wafer body 400 are stacked;

Step S340, the protective material is filled in the second crack-stopping through-silicon-via 240.

In step S310, as shown in FIG. 10, a first crack-stopping through-silicon-via 230 may be formed on the side of the scribe line 120 (not shown in FIG. 10) on the first wafer body 300. In the case of multiple wafer stacking, one can first form a blind hole 210 on each wafer body, then thin the wafer body 100 after filling the holes with protective material, at the end bond the multiple wafers, however the process is rather complicated. Therefore, it is possible to make a two-wafer stack structure first, then form a crack-stopping through-silicon-via on each of the wafer body 100, this process can simplify the manufacturing process and improve the production efficiency. For example, the two-wafer stack structure includes a first wafer body 300 and a second wafer body 400 that are stuck together. A first crack-stopping through-silicon-via 230 may be formed on the the first wafer body 300 to expose the interfacial surface of the second wafer 400. The first crack-stopping through-silicon-vias 230 is filled with a protective material. Then a second crack-stopping through-silicon-via 240 is formed on the surface of the second wafer body 400. The second crack-stopping through-silicon-via 240 aligns exactly with the first crack-stopping through-silicon-via 230, exposing surface of the first crack-stopping through-silicon-via 230. Then the second crack-stopping through-silicon-via 240 is filled with the protective material. This process eliminates the thinning step, therefore it simplifies the manufacturing process.

Wherein, the first crack-stopping through-silicon-via 230 may be formed by dry etching, wet etching, laser etching, or combined dry and wet etching. For example, dry etching may be reactive ion etching or inductively coupled plasma etching, and wet etching may be etching with hydrofluoric acid solution, hydrofluoric acid buffered etching solution, potassium hydroxide solution, or TMAH solution. The first crack-stopping through-silicon-via 230 is located at the side of the scribe line 120, and the cross section of the first crack-stopping through-silicon-via 230 may be rectangular or trapezoidal.

It should be noted that the position of the first crack-stopping through-silicon-via 230 can be defined by photoresist, the photoresist can be coated on the surface of the first wafer body 300, and the exposure can be carried out through the corresponding mask, and the mask transfers its pattern to the photoresist layer; by developing, the photoresist layer is exposed to the area where the first crack-stopping through-silicon-via 230 is to be opened; and the first crack-stopping through-silicon-via 230 is formed by etching.

In step S320, a protective material may be filled in the first crack-stopping through-silicon-via 230. The protective material can be one or more of the conductive materials such as copper, tungsten, aluminum, tantalum, titanium, tantalum nitride, and titanium nitride. At this time, before the protective material, a layer of insulating material can be filled within the walls of the first crack-stopping through-silicon-via 230. And the insulating material layer is formed on the surface of the wafer body 100 as well. The insulating layer can be formed, for example, by chemical vapor deposition, physical vapor deposition or thermal growth. The above-mentioned conductive material can be filled in the first crack-stopping through-silicon-via 230, for example, by electroplating. In electroplating, first, a seed layer is deposited on the surface of the insulating layer, then a metal protective layer is electroplated on the seed layer. During the electroplating process, the metal layer is also formed on the surface of the wafer body 100, and the metal layer needs to be removed, for example, by etching or chemical mechanical polishing.

When the filling material is one or more of silicon oxide, silicon nitride, silicon oxynitride, silicon carbide, silicon carbonitride, polyimide, and tetraethyl orthosilicate, deposition techniques such as chemical vapor deposition or physical vapor deposition or thermal growth are applied. At the same time, a protective material layer 20 is also formed on the surface of the first wafer body 300. At this time, whether the protective material layer 20 is removed or not removed can be decided by actual needs. Further, air gaps 250 may be formed between the protective material flayers filled in the first crack-stopping through-silicon-via 230.

In step S330, as shown in FIG. 11, a second crack-stopping through-silicon-via 240 may be formed to the side of the scribe lane 120 (not shown in FIG. 11) on the second wafer body 400 and aligned to the first crack-stopping through-silicon-via 230. Herein, the second crack-stopping through-silicon-via 240 may be formed by dry etching, wet etching, laser etching, or dry-wet combined etching. For example, dry etching may be reactive ion etching or inductively coupled plasma etching, and wet etching may be potassium hydroxide solution etching. The second crack-stopping through-silicon-via 240 is located on the side of the scribe line 120 (not shown in this figure), and the cross-section of the second crack-stopping through-silicon-via 240 may be rectangular or trapezoidal.

It should be noted that the position of the second crack-stopping through-silicon-via 240 can be defined by photoresist. The photoresist is coated on the surface of the second wafer body 400, and the lithography exposure is performed through the corresponding photomask, and the photomask pattern is transferred to the photoresist layer; through photoresist development, the photoresist layer opens in the area where the second crack-stopping through-silicon-via 240 is; the second crack-stopping through-silicon-via 240 is formed by etching.

In step S340, the second crack-stopping through-silicon-via 240 is filled with the protective material. The protective material can be one or more of the conductive materials such as copper, tungsten, aluminum, tantalum, titanium, tantalum nitride, and titanium nitride. At this time, before the protective material, a layer of insulating material can be filled within the walls of the second crack-stopping through-silicon-via 240. And the insulating material layer is formed on the surface of the wafer body 100 as well. The insulating layer can be formed, for example, by chemical vapor deposition, physical vapor deposition or thermal growth. The above-mentioned conductive material can be filled in the second crack-stopping through-silicon-via 240, for example, by electroplating. In electroplating, first, a seed layer is deposited on the surface of the insulating layer, then a metal protective layer is electroplated on the seed layer. During the electroplating process, the metal layer is also formed on the surface of the wafer body 100, and the metal layer needs to be removed, for example, by etching or chemical mechanical polishing.

When the filling material is one or more of silicon oxide, silicon nitride, silicon oxynitride, silicon carbide, silicon carbonitride, polyimide, and tetraethyl orthosilicate, deposition techniques such as chemical vapor deposition or physical vapor deposition or thermal growth are applied. At the same time, a protective material layer 20 is also formed on the surface of the first wafer body 400. At this time, whether the protective material layer 20 is removed or not removed can be decided by actual needs. Further as shown in FIG. 13, air gaps 250 may be formed between the protective material layers filled in the second crack-stopping through-silicon-via 240.

In the case of more wafer stacked together, following the double-wafer stack structure of the first crack-stopping through-silicon-via 230 and the second crack-stopping through-silicon-via 240, each additional stacked wafer can apply the same technique by stacking the wafer to the pile first and forming the crack-stopping through-silicon-via which aligns to the prior vias. This method of first stacking and then forming the crack-stopping through-silicon-vias can simplify the manufacturing process and improve the production efficiency.

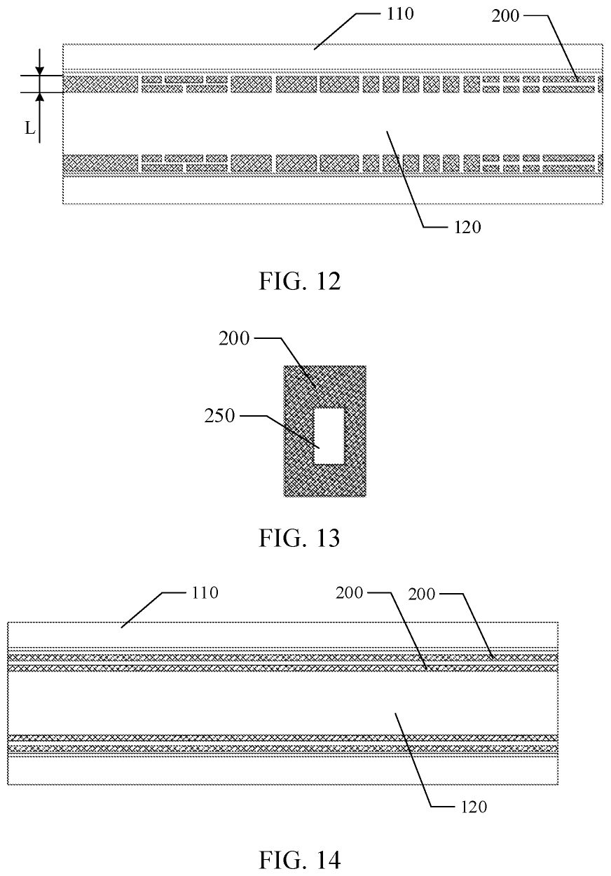

As shown in FIG. 12, crack-stopping through-silicon-vias 200 are formed on both sides of the scribe lane 120 along scribe lane extending direction. Of course, in practical applications, crack-stopping through-silicon-vias 200 may also be provided on only one side of the scribe lane 120. The embodiment of the present disclosure does not limit at this. The crack-stopping through-silicon-vias 200 include continuously distributed crack-stopping through-silicon-vias or separated distributed crack-stopping through-silicon-vias. Multiple rows of crack-stopping through-silicon-vias 200 can be formed on one side of the scribe lane 120. The width L of the crack-stopping through-silicon-vias 200 ranges from 2 μm to 20 μm, and the depth S of the crack-stopping through-silicon-vias 200 ranges from 15 μm to 150 μm. When there are multiple rows of crack-stopping through-silicon-vias 200 on one side of the scribe lane 120, the width L of the entire area of the crack-stopping through-silicon-vias ranges from 2 μm to 20 μm. The width of the crack-stopping through-silicon-vias 200 refers to the width between the sidewalls of the crack-stopping through-silicon-vias 200 wherein the vias are formed along a line parallel to the scribe line 120.

As shown in FIG. 14 herein, multiple rows of crack-stopping through-silicon-vias 200 can be provided on one side of the scribe lane 120, and multiple rows of crack-stopping through-silicon-vias 200 can be arranged in parallel in the scribe lane 120. Multiple rows of crack-stopping through-silicon-vias can further ease the cutting stress.

The wafer fabrication method provided by the embodiments of the present disclosure effectively prevented damaging the die region 110 from the cutting stress during wafer scribe, by providing the crack-stopping through-silicon-vias 200, which are filled with protective materials and arranged on both sides of the scribe lane 120. Thus, the crack-stopping through-silicon-vias 200 can effectively reduce the width of the scribe lane 120, miniaturize of the scribe lane 120 and improve the resultant wafer utilization rate, and ultimately leading to cost reduction of the chip.

This exemplary embodiment also provides a wafer, the wafer includes a wafer body 100 and crack-stopping through-silicon-vias 200 as shown in FIG. 4. The wafer body 100 is provided with a scribe channel for die cutting. 120. The crack-stopping through-silicon-vias 200 are provided on the side of the scribe lane 120, and the crack-stopping through-silicon-vias 200 are filled with a protective material.

The wafer provided by the embodiment of the present disclosure has mitigated the cutting stress induced damage on die region 110 during wafer scribe, by having the crack-stopping through-silicon-vias 200 filled with protective material formed on both sides of the scribe lane 120. Thus, the crack-stopping through-silicon-vias 200 can effectively reduce the width of the scribe lane 120, and the miniaturize the scribe lane 120, thus, improves the effective utilization rate of the wafer as the result.

The wafer body 100 can be divided into a scribe lane 120 and a die area 110. The scribe knife acts on the scribe lane 120 during cutting, and the die area 110 is untouched. The wafer body 100 may be a basic silicon wafer covered with a silicon epitaxial layer, silicon on an insulator layer, etc., or a base substrate of other semiconductor materials such as GaN, and the substrate may be an intrinsic semiconductor substrate, or N-type doped or P-type doped semiconductor substrate, all of which do not limit the embodiments of the present disclosure. A dielectric layer may be disposed on the substrate, and the material of the dielectric layer may be one or more of silicon oxide, silicon nitride, and silicon oxynitride. In specific implementation, the dielectric layer may be formed by methods such as chemical vapor deposition, atomic layer deposition, and the like. It is understandable that the dielectric layer may be a single layer of insulating material, or may be formed by stacking multiple layers of the same or different insulating materials.

The disclosed crack-stopping through-silicon-vias 200 are formed on both sides of the scribe lane 120 along the scribing direction. Of course, in practical applications, the crack-stopping through-silicon-vias 200 may also be provided on one side of the scribe lane 120. The embodiment of the present disclosure does not limit this aspect. The crack-stopping through-silicon-vias 200 include continuously distributed through-silicon vias or separately distributed through silicon vias. Multiple rows of crack-stopping through-silicon-vias 200 are formed on one side of the cutting lane 120. The width L of the crack-stopping through-silicon-vias 200 ranges from 2 μm to 20 μm, and the depth S of the crack-stopping through-silicon-vias 200 ranges from 15 μm to 150 μm. When there are multiple rows of the crack-stopping through-silicon-vias 200 on one side of the scribe lane 120, the total width L of the entire area of the crack-stopping through-silicon-vias ranges from 2 μm to 20 μm. The width of the crack-stopping through-silicon-vias 200 refers to the width between the outer edges of the sidewalls of the crack-stopping through-silicon-vias 200 wherein the vias are formed along a line parallel to the scribe line 120.

The protective materials may include one or more of: copper, tungsten, aluminum, tantalum, titanium, tantalum nitride, titanium nitride, silicon oxide, silicon nitride, silicon oxynitride, silicon carbide, silicon carbon nitride, polyimide, and tetraethyl orthosilicate. Further, air gaps 250 are provided inside the crack-stopping through-silicon-vias 200.

When the protective material is one or more of conductive materials such as copper, tungsten, aluminum, tantalum, titanium, tantalum nitride, and titanium nitride, the crack-stopping through-silicon-vias 200 may include an insulating layer and a protective material layer. The insulating layer is located between the through-via sidewalls on the wafer body 100 and the protective material. Before filling the protective material, an insulating layer may be formed first on the through-via sidewalls and the first surface of the wafer body 100. The insulating layer can be formed by chemical vapor deposition, physical vapor deposition or thermal growth as examples. The above-mentioned conductive material is filled in the through-silicon-vias by electroplating for example. In electroplating, first a seed layer is deposited on the insulating layer, and a metal protective layer is electroplated on the seed layer.

When the filling material is one or more of silicon oxide, silicon nitride, silicon oxynitride, silicon carbide, silicon carbonitride, polyimide, and tetraethyl orthosilicate, the deposition method may be chemical vapor deposition or physical vapor deposition or thermal growth. At the same time, a protective material layer 20 is formed on the first surface of the wafer body 100. At this time, the protective material layer can be removed or not removed according to actual needs. Further, air gaps 250 may be formed inside the protective materials filled in the blind holes 210.

The wafer disclosed by the embodiment is provided with the crack-stopping through-silicon-vias 200 which are filled with protective material and disposed on both sides of the scribe lane 120. The die region 110 is protected from damage by the cutting stress during wafer scribing. Thus, the crack-stopping through-silicon-vias 200 can successfully reduce the width of the scribe lane 120, and improve the effective utilization rate of the wafer, therefore saving the chip cost.

This exemplary embodiments also provide a semiconductor device, which includes multiple aforementioned stacked wafers. There are crack-stopping through-silicon-vias 200 on both sides of the scribe lane 120 in each of the stacked wafers. The positions of the scribe lanes 120 of the multiple wafers align to each other. After the multiple wafers are stacked, the scribe lanes 120 of the multilayer wafers overlap in their projections on each wafer. As the stacked wafers are cut along the scribe lane 120, a plurality of stacked dies are obtained.

Those skilled in the art will easily think of other embodiments of the present disclosure after considering the specification and practicing the invention disclosed herein. This application is intended to cover any variations, uses, or adaptive changes of the present disclosure. These variations, uses, or adaptive changes follow the general principles of the present disclosure and include common knowledge or conventional technical means in the technical field not disclosed in the present disclosure. The description and the embodiments are only regarded as exemplary, and the true scope and spirit of the present disclosure are pointed out by the appended claims.

What is claimed is:

1. A wafer manufacturing method, comprising:
providing a first wafer having a first scribe lane for die cutting;
forming a plurality of first crack-stopping through-silicon-vias (TSVs) on a side of the first scribe lane, wherein each of the plurality of first crack-stopping TSVs is filled with a protective material.

2. The wafer manufacturing method of claim 1, wherein the plurality of first crack-stopping TSVs are formed on a first surface of the first wafer, wherein the plurality of first crack-stopping TSVs comprises blind vias which do not penetrate a full thickness of the first wafer, wherein the blind vias are filled with the protective material; wherein the first wafer has a second surface opposite to the first surface; and
wherein the wafer manufacturing method further comprises thinning the second surface of the first wafer until the blind vias are exposed.

3. The wafer manufacturing method of claim 1, further comprising:
providing a second wafer having a second scribe lane for die cutting;
forming a plurality of second crack-stopping TSVs on a side of the second scribe lane, wherein the second wafer is stacked with the first wafer;
wherein the plurality of second crack-stopping TSVs each is aligned to one of the plurality of first crack-stopping TSVs; and
wherein each of the plurality of second crack-stopping TSVs is filled with the protective material.

4. The wafer manufacturing method of claim 1, wherein the plurality of first crack-stopping TSVs is formed on both sides and along an extending direction of the first scribe lane.

5. The wafer manufacturing method of claim 4, wherein the plurality of first crack-stopping TSVs comprises continuously distributed or separately distributed crack-stopping TSVs.

6. The wafer manufacturing method of claim 4, wherein the plurality of first crack-stopping TSVs is distributed in multiple rows on one side of the scribe lane.

7. The wafer manufacturing method of claim 1, wherein a width of each of the plurality of first crack-stopping TSVs is in the range from 2 microns to 20 microns, and a depth of each of the plurality of first crack-stopping TSVs is in the range from 15 microns to 150 microns.

8. The wafer manufacturing method of claim 1, wherein the protective material comprises one or more of copper, tungsten, aluminum, tantalum, titanium, tantalum nitride, titanium nitride, silicon oxide, silicon nitride, silicon oxynitride, carbide silicon, silicon carbonitride, polyimide and tetraethyl orthosilicate.

9. The wafer manufacturing method according to claim 8, wherein an air gap is provided in one of the plurality of first crack-stopping TSVs.

10. A wafer, comprising:
a wafer substrate, having a scribe lane for die cutting;
a plurality of crack-stopping TSVs on a side of the scribe lane, wherein each of the plurality of crack-stopping TSVs is filled with a protective material.

11. The wafer of claim 10, wherein the plurality of crack-stopping TSVs is formed on both sides and along an extending direction of the scribe lane.

12. The wafer of claim 11, wherein the plurality of crack-stopping TSVs comprises continuously distributed or separately distributed crack-stopping TSVs.

13. The wafer of claim 11, wherein the plurality of crack-stopping TSVs is distributed in multiple rows on one side of the scribe lane.

14. The wafer according to claim 10, wherein a width of each of the plurality of crack-stopping TSVs is in the range from 2 microns to 20 microns, and a depth of each of the plurality of crack-stopping TSVs is in the range from 15 microns to 150 microns.

15. The wafer of claim 10, wherein the protective material comprises one or more of copper, tungsten, aluminum, tantalum, titanium, tantalum nitride, titanium nitride, silicon oxide, silicon nitride, silicon oxynitride, carbide silicon, silicon carbonitride, polyimide and tetraethyl orthosilicate.

16. The wafer of claim 15, wherein an air gap is provided in one of the plurality of crack-stopping TSVs.

17. A semiconductor device, comprising multiple wafers each disclosed according to claim 10, wherein said multiple wafers are stacked together.
